(19) United States
(12) Patent Application Publication
(10) Pub. No.: US 2011/0062533 A1
(43) Pub. Date: Mar. 17, 2011

(54) Device package substrate and method of manufacturing the same

(75) Inventors: Seung Wook Park, Suwon (KR); Hyung Jin Jeon, Gunpo (KR); Young Do Kweon, Seoul (KR)

(73) Assignee: SAMSUNG ELECTRO-MECHANICS CO., LTD., Suwon (KR)

(21) Appl. No.: 12/654,417

(22) Filed: Dec. 18, 2009

(30) Foreign Application Priority Data
Sep. 11, 2009 (KR) 10-2009-0085928

(51) Int. Cl. H01L 23/498; H01L 21/60

(52) U.S. Cl. 257/416; 438/51; 257/E23.068; 257/E21.508

(57) ABSTRACT

A device package substrate includes: a substrate having a cavity formed on a top surface thereof, the cavity having a chip mounting region; a first interconnection layer formed to extend to the inside of the cavity; a second interconnection layer formed to be spaced apart from the first interconnection layer; a chip positioned in the chip mounting region so as to be connected to the first and second interconnection layers; an insulating layer formed to cover the first and second interconnection layers and the chip and having a contact hole exposing a part of the second interconnection layer; and a bump pad formed in the contact hole so as to be connected to external elements.

### CROSS-REFERENCE TO RELATED APPLICATIONS

This application claims the priority of Korean Patent Application No. 10-2009-0085928 filed on Sep. 11, 2009, in the Korean Intellectual Property Office, the disclosure of which is incorporated herein by reference.

### BACKGROUND OF THE INVENTION

1. Field of the Invention

The present invention relates to a device package substrate and a method of manufacturing the same, and more particularly, to a device package substrate and a method of manufacturing the same, which implements a device package substrate having a chip mounted in a cavity to reduce the overall system area through a manufacturing process simpler than existing processes.

2. Description of the Related Art

Recently, with the continuing development of the electronics industry, demand for miniaturized high performance electronic parts has increased rapidly.

To cope with such a trend, high-density package substrates or circuit patterns are now required. Accordingly, various methods for implementing micro circuit patterns are being designed and implemented.

An embedded process, which is one of the methods for implementing micro circuit patterns, is suitable for micro circuit patterns. In a structure formed by the embedded process, a circuit is buried in an insulating material. Therefore, the flatness and rigidity of a product may be improved, and the circuit is unlikely to be damaged.

In an embedding process according to the related art, a package or device is directly mounted on a substrate or stacked to form a substrate. In this case, it is possible to reduce the overall package area, when a package is mounted on either surface or both surfaces.

Accordingly, a great deal of research into the embedding process and the structure of active devices and RLC devices is currently being undertaken.

A sensor such as a surface acoustic wave (SAW) filter or a micro electro mechanical system (MEMS), which requires a cavity or gap, may be mounted within a substrate because it has a small size. However, current research regarding such a sensor is insufficient.

### SUMMARY OF THE INVENTION

An aspect of the present invention provides a device package substrate and a method of manufacturing the same, which implements a device package substrate having a chip mounted in a cavity to reduce the overall system area through a manufacturing process simpler than existing processes.

According to an aspect of the present invention, there is provided a device package substrate including: a substrate having a cavity formed in a top surface thereof, the cavity having a chip mounting region; a first interconnection layer formed to extend to the inside of the cavity; a second interconnection layer formed to be spaced apart from the first interconnection layer; a chip positioned in the chip mounting region so as to be connected to the first and second interconnection layers; an insulating layer formed to cover the first and second interconnection layers and the chip and having a contact hole exposing a part of the second interconnection layer; and a bump pad formed in the contact hole so as to be connected to external elements.

The device package substrate may further include a third interconnection layer formed to be spaced apart from the first and second interconnection layers.

The third interconnection layer may be connected to the external elements through a solder bump or bonding wire.

The device package substrate may further include a connection member formed through the substrate or the insulating layer so as to be connected to at least one of the first to third interconnection layers.

The connection member may be connected to the external elements through a solder bump or bonding wire.

The device package substrate may further include a molding resin layer molding the connected external elements.

The chip may be at least one selected from a surface acoustic wave (SAW) filter, a bulk acoustic wave (BAW) filter, a micro electro mechanical system (MEMS), and a sensor.

According to another aspect of the present invention, there is provided a device package substrate including: a substrate having a cavity formed in a top surface thereof, the cavity having a chip mounting region; an interconnection layer formed around the cavity; a chip positioned in the cavity so as to be connected to the interconnection layer; and an insulating layer formed on the substrate so as to cover the interconnection layer and the chip.

According to another aspect of the present invention, there is provided a method of manufacturing a device package substrate, the method including: forming a cavity in at least a region of a top surface of a substrate partitioned into a plurality of regions, the cavity having a chip mounting region; forming a first interconnection layer around the cavity; forming a second interconnection layer spaced apart from the first interconnection layer; mounting a chip in the chip mounting region, the chip connected to the first interconnection layer; forming an insulating layer to cover the first and second interconnection layers and the chip; forming a contact hole in the insulating layer to expose a part of the second interconnection layer; and forming a bump pad in the contact hole, the bump pad connected to external elements.

The cavity may be formed by etching or punching the substrate.

The first and second interconnection layers may be formed to extend to the inside of the cavity.

The method may further include forming a third interconnection layer to be spaced apart from the first and second interconnection layers.

The third interconnection layer may be connected to the external elements through a solder bump or bonding wire.

The method may further include forming a connection member connected to at least one of the first to third interconnection layers.

The connection member may be connected to the external elements through a solder bump or bonding wire.

The method may further include forming a molding resin layer molding the connected external elements.

The method may further include cutting the substrate partitioned into the plurality of regions to form individual device packages.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1A to 1C are schematic cross-sectional views for explaining a method of manufacturing a device package substrate according to an embodiment of the preset invention;

FIG. 2 is a schematic cross-sectional view of a device package substrate formed by the method according to the embodiment of the present invention;

FIG. 3 is a schematic cross-sectional view of another device package substrate formed by the method according to the embodiment of the present invention;

FIGS. 4A to 4C are schematic cross-sectional views for explaining a method of manufacturing a device package substrate according to another embodiment of the present invention;

FIG. 5 is a schematic cross-sectional view of a device package substrate formed by the method according to the embodiment of the present invention; and

FIG. 6 is a schematic cross-sectional view of another device package substrate formed by the method according to the embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. Like reference numerals in the drawings denote like elements, and thus their description will be omitted.

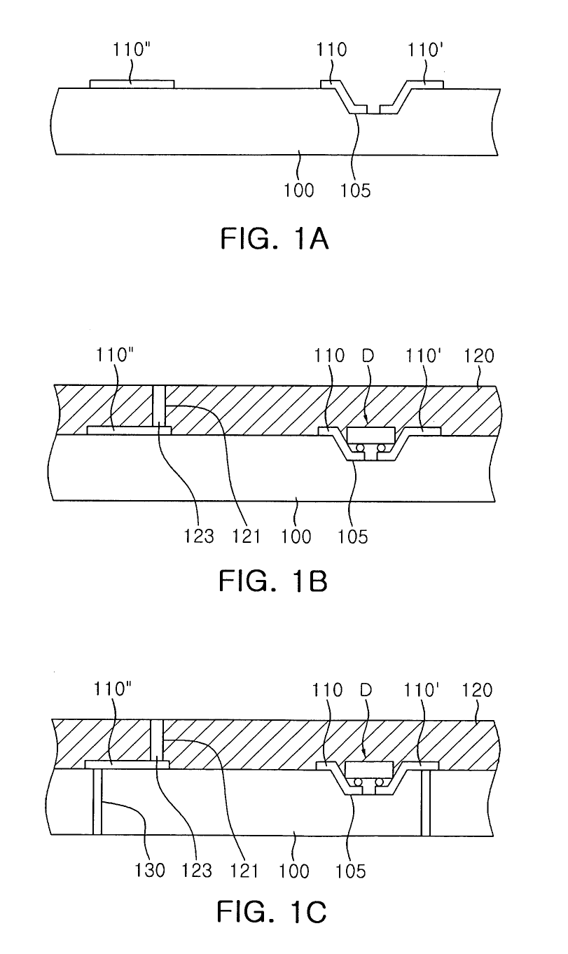

Hereinafter, a device package substrate and a method of manufacturing the same according to an embodiment of the present invention will be described with reference to FIG. 1A to FIG. 3.

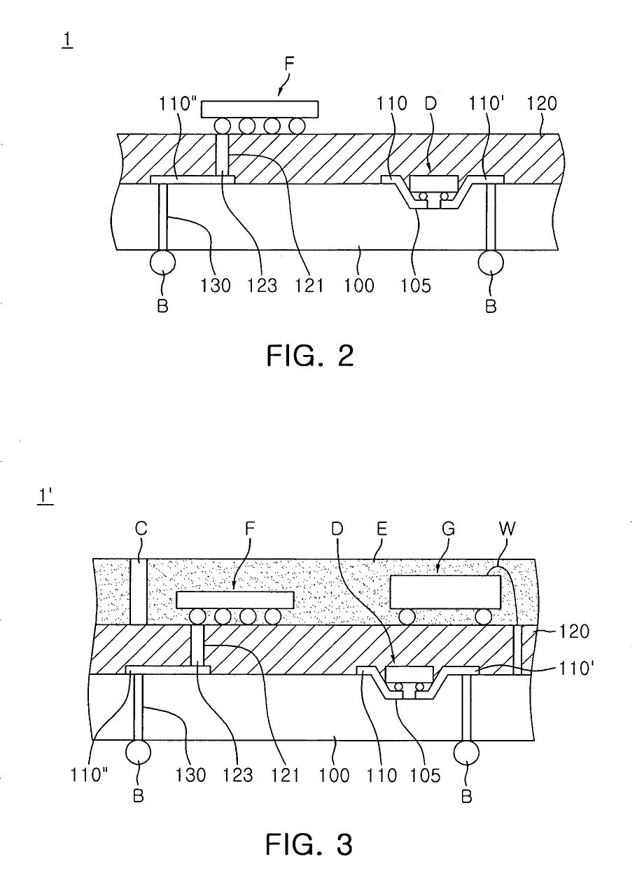

FIGS. 1A to 1C are schematic cross-sectional views for explaining a method of manufacturing device package substrates 1 and 1′ according to an embodiment of the preset invention. FIGS. 2 and 3 are schematic cross-sectional views of the device package substrate 1 and 1′ formed by the method according to the embodiment of the present invention.

Each device package substrate 1 and 1′ according to the embodiment of the present invention includes a substrate 100, a first interconnection layer 110, a second interconnection layer 110′, a chip D, an insulating layer 120, and a bump pad 123. The substrate 100 has a cavity 105 formed in the top surface thereof, the cavity 105 having a chip mounting region. The first interconnection layer 110 is formed to extend to the inside of the cavity 105, and the second interconnection layer 110′ is formed to be spaced apart from the first interconnection layer 110. The chip D is positioned in the chip mounting region so as to be connected to the first and second interconnection layers 110 and 110′. The insulating layer 120 is formed to cover the first and second interconnection layers 110 and 110′ and the chip D and has a contact hole 121 exposing a part of the third interconnection layer 110″. The bump pad 123 is formed in the contact hole 121 in order for connection with external elements F and G.

First, as shown in FIG. 1A, the prepared substrate 100 is etched to form the cavity 105. The cavity 105 may be formed by etching or punching the substrate 100.

Subsequently, the first and second interconnection layers 110 and 110′ are formed inside the cavity 105 formed in the substrate 100. The first and second interconnection layers 110 and 110′ may be formed to extend to the inside of the cavity 105, and spaced apart from each other.

Furthermore, a third interconnection layer 110″ may be formed to be spaced apart from the first and second interconnection layers 110 and 110′. The third interconnection layer 110″ may be connected to the external elements F and G through a solder bump B or bonding wire W.

Next, as shown in FIG. 1B, the chip D is mounted in the cavity 105 so as to be connected to the first and second interconnection layers 110 and 110′ in the cavity 105.

The mounted chip D may be at least one selected from a surface acoustic wave (SAW) filter, a bulk acoustic wave (BAW) filter, a micro electro mechanical system (MEMS), and a sensor. The chip D requires a cavity for resonance, and the cavity 105 may be used as the cavity for resonance.

Subsequently, as shown in FIG. 1C, the insulating layer 120 is formed to cover the first to third interconnection layers 110 to 110″ and the chip D. After an insulating material layer (not shown) is formed on the substrate 100, a photosensitive resin layer (not shown) is applied to the insulating material layer, and then exposed and developed using a mask (not shown) with a predetermined pattern, thereby forming the insulating layer 120 having the contact hole 121.

The bump pad 123 which may be connected to the external elements F and G may be provided in the contact hole 121 of the insulating layer 120, and may include at least one conductive layer.

Furthermore, a connection member 130 may be formed through the inside of the substrate 100 or the insulating layer 120 so as to be connected to at least one of the first to third interconnection layers 110 to 110″. The connection member 130 may be formed of a conductive metallic bar.

Referring to FIGS. 2 and 3, the connection member 130 may be electrically connected to the external elements F and G through the solder bump B or the bonding wire W. A region connected to the external element G through the bonding wire W may be molded with an epoxy resin layer E.

As shown in FIG. 3, an external connection terminal C may be further formed in the epoxy resin layer E. The external connection terminal C may be formed in the insulating layer 120.

According to the embodiment of the present invention, there is a process advantage in that the substrate 100 partitioned into a plurality of regions may be cut to form individual device package substrates 1 and 1′.

Furthermore, as a device package including passive elements is implemented as individual device package substrates, the device package may be applied to radio frequency devices and high power devices. Compared with a device according to the related art, which includes passive elements built therein using only a thin film process, the manufacturing process according to the embodiment of the present invention is simple, and the overall system area may be reduced.

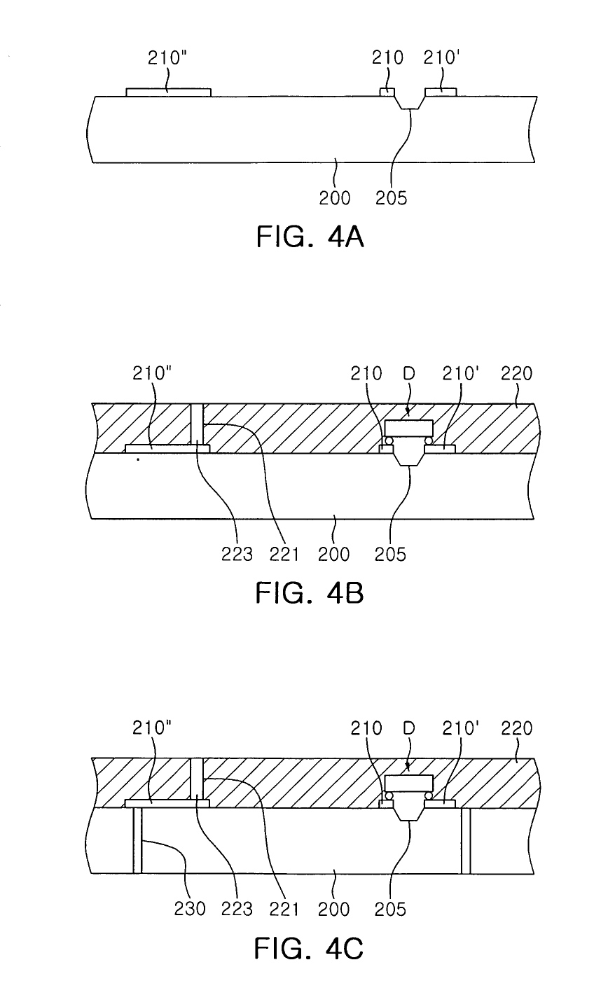

Hereinafter, a method of manufacturing a device package substrates 2 and 2′ according to another embodiment of the present invention and the device package substrate 2 and 2′ formed by the method will be described with reference to FIGS. 4A to 6.

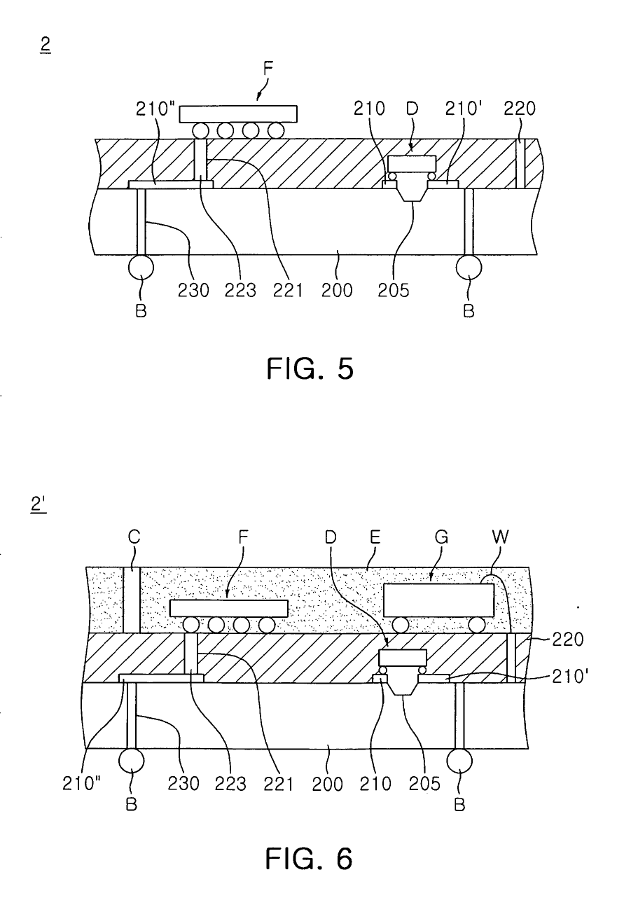

FIGS. 4A to 4C are schematic cross-sectional views for explaining a method of manufacturing device package substrates 2 and 2′ according to the embodiment of the present invention. FIGS. 5 and 6 are schematic cross-sectional views of the device package substrates 2 and 2′ formed by the method according to the embodiment of the present invention.

Each of the device package substrates 2 and 2′ according to the embodiment of the present invention may include a substrate 200, a first interconnection layer 210, a second interconnection layer 210′, a chip D, an insulating layer 220, and a bump pad 223. The substrate 200 has a cavity 205 formed on the top surface thereof, the cavity 205 having a chip mounting region. The first interconnection layer 210 is formed around the cavity 205, and the second interconnection layer 210′ is formed to be spaced apart from the first interconnection layer 210. The chip D is positioned in the chip mounting region so as to be connected to the first and second interconnection layers 210 and 210′. The insulating layer 220 is formed to cover the first and second insulating layers 210 and 210′ and the chip D, and has a contact hole 221 exposing a part of the third interconnection layer 210″. The bump pad 223 is formed in the contact hole 221 in order for connection with external elements F and G.

First, as shown in FIG. 4A, the prepared substrate 200 is etched to form the cavity 205. The cavity 205 may be formed by etching or punching the substrate 200.

Subsequently, the first and second interconnection layers 210 and 210′ are formed around the cavity 205. Specifically, the first and second interconnection layers 210 and 210′ are not formed in the cavity 205, but formed around the cavity 205, unlike the above-described embodiment. The first and second interconnection layers 210 and 210′ may be formed to be spaced apart from each other.

Furthermore, a third interconnection layer 210″ may be formed to be spaced apart from the first and second interconnection layers 210 and 210′. The third interconnection layer 210″ may be connected to the external elements F and G through a solder bump B or bonding wire W.

Next, as shown in FIG. 4B, the chip D is mounted in the cavity 205 so as to be connected to the first and second interconnection layers 210 and 210′ formed around the cavity 205.

The mounted chip D may be at least one selected from a SAW filter, a BAW filter, a MEMS, and a sensor. The chip D requires a cavity for resonance, and the cavity 205 may be used as the cavity for resonance.

Subsequently, as shown in FIG. 4C, the insulating layer 220 is formed to cover the first to third interconnection layers 210 to 210″ and the chip D. After an insulating material layer (not shown) is formed on the substrate 200, a photosensitive resin layer (not shown) is applied onto the insulating material layer, and then exposed and developed using a mask (not shown) with a predetermined pattern, thereby forming the insulating layer 220 having the contact hole 221.

The bump pad 223 which may be connected to the external elements F and G may be formed in the contact hole 221 of the insulating layer 220, and may include at least one conductive layer.

Furthermore, a connection member 230 may be formed through the inside of the substrate 200 or the insulating layer 220 so as to be connected to at least one of the first to third interconnection layers 110 to 110″. The connection member 230 may be formed of a conductive metallic bar.

Referring to FIGS. 5 and 6, the connection member 230 may be electrically connected to the external elements F and G through the solder bump B or the bonding wire W. A region connected to the external element G through the bonding wire W may be molded with an epoxy resin layer E.

As shown in FIG. 6, an external connection terminal C may be further formed in the epoxy resin layer E. The external connection terminal C may be formed in the insulating layer 120.

According to the embodiment of the present invention, there is a process advantage in that the substrate 200 partitioned into a plurality of regions may be cut to form individual device package substrates 2 and 2′.

Throughout the above-described embodiment, the device package substrate may be a silicon substrate, an HTCC substrate, an LTCC substrate, a substrate containing ceramic materials or the like.

Furthermore, as a device package including passive elements is implemented as individual device package substrates, the device package may be applied to radio frequency devices and high power devices. Compared with a device according to the related art, which includes passive elements built therein using only a thin film process, the manufacturing process according to the embodiment of the present invention is simple, and the complexity of the overall system area may be reduced.

In the above-described embodiments, it has been described that the insulating layer of the device package substrate has a single-layer structure. Without being limited thereto, however, the insulating layer may have a multi-layer structure in order to mount a plurality of passive elements.

According to the embodiments of the present invention, it is possible to provide a device package substrate and a method of manufacturing the same, which implements a device package substrate having a chip mounted in a cavity to reduce the overall system area through a simper manufacturing process than existing processes.

While the present invention has been shown and described in connection with the exemplary embodiments, it will be apparent to those skilled in the art that modifications and variations can be made without departing from the spirit and scope of the invention as defined by the appended claims.

What is claimed is:

1. A device package substrate comprising:
a substrate having a cavity formed in a top surface thereof, the cavity having a chip mounting region;
a first interconnection layer formed to extend to the inside of the cavity;
a second interconnection layer formed to be spaced apart from the first interconnection layer;
a chip positioned in the chip mounting region so as to be connected to the first and second interconnection layers;
an insulating layer formed to cover the first and second interconnection layers and the chip and having a contact hole exposing a part of the second interconnection layer; and
a bump pad formed in the contact hole so as to be connected to external elements.

2. The device package substrate of claim 1, further comprising a third interconnection layer formed to be spaced apart from the first and second interconnection layers.

3. The device package substrate of claim 2, wherein the third interconnection layer is connected to the external elements through a solder bump or bonding wire.

4. The device package substrate of claim 2, further comprising a connection member formed through the substrate or the insulating layer so as to be connected to at least one of the first to third interconnection layers.

5. The device package substrate of claim 4, wherein the connection member is connected to the external elements through a solder bump or bonding wire.

6. The device package substrate of claim 1, further comprising a molding resin layer molding the connected external elements.

7. The device package substrate of claim 1, wherein the chip is at least one selected from a surface acoustic wave (SAW) filter, a bulk acoustic wave (BAW) filter, a micro electro mechanical system (MEMS), and a sensor.

8. A device package substrate comprising:
a substrate having a cavity formed in a top surface thereof, the cavity having a chip mounting region;
a first interconnection layer formed around the cavity;
a second interconnection layer formed to be spaced apart from the first interconnection layer;
a chip positioned in the chip mounting region so as to be connected to the first and second interconnection layers;
an insulating layer formed to cover the first and second interconnection layers and the chip and having a contact hole exposing a part of the second interconnection layer; and
a bump pad formed in the contact hole so as to be connected to external elements.

9. The device package substrate of claim 8, further comprising a third interconnection layer formed to be spaced apart from the first and second interconnection layers.

10. The device package substrate of claim 9, wherein the third interconnection layer is connected to the external elements through a solder bump or bonding wire.

11. The device package substrate of claim 8, further comprising a connection member formed through the substrate or the insulating layer so as to be connected to the first or second interconnection layer.

12. The device package substrate of claim 11, wherein the connection member is connected to the external elements through a solder bump or bonding wire.

13. The device package substrate of claim 8, further comprising a molding resin layer molding the connected external elements.

14. The device package substrate of claim 8, wherein the chip is at least one selected from a SAW filter, a BAW filter, a MEMS, and a sensor.

15. A device package substrate comprising:
a substrate having a cavity formed in a top surface thereof, the cavity having a chip mounting region;
an interconnection layer formed around the cavity;
a chip positioned in the cavity so as to be connected to the interconnection layer; and
an insulating layer formed on the substrate so as to cover the interconnection layer and the chip.

16. A method of manufacturing a device package substrate, the method comprising:
forming a cavity in at least a region of a top surface of a substrate partitioned into a plurality of regions, the cavity having a chip mount region;
forming a first interconnection layer around the cavity;
forming a second interconnection layer spaced apart from the first interconnection layer;
mounting a chip in the chip mounting region, the chip connected to the first interconnection layer;
forming an insulating layer to cover the first and second interconnection layers and the chip;
forming a contact hole in the insulating layer to expose a part of the second interconnection layer; and
forming a bump pad in the contact hole, the bump pad connected to external elements.

17. The method of claim 16, wherein the cavity is formed by etching or punching the substrate.

18. The method of claim 16, wherein the first and second interconnection layers are formed to extend to the inside of the cavity.

19. The method of claim 16, further comprising forming a third interconnection layer to be spaced apart from the first and second interconnection layers.

20. The method of claim 19, wherein the third interconnection layer is connected to the external elements through a solder bump or bonding wire.

21. The method of claim 19, further comprising forming a connection member connected to at least one of the first to third interconnection layers.

22. The method of claim 21, further comprising connecting the external elements and the connection member through a solder bump or wire bonding.

23. The method of claim 16, further comprising forming a molding resin layer molding the connected external elements.

24. The method of claim 16, further comprising cutting the substrate partitioned into the plurality of regions to form individual device packages.
